(19) United States
(12) Patent Application Publication
(10) Pub. No.: US 2009/0176351 A1
(43) Pub. Date: Jul. 9, 2009

(54) STRUCTURE AND METHOD TO IMPROVE MOSFET RELIABILITY

(75) Inventors: HUILONG ZHU, Poughkeepsie, NY (US); Tai-chi Su, Woodbury, CT (US); Ying Li, Newburgh, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignee: INTERNATIONAL BUSINESS MACHINES CORPORATION, ARMONK, NY (US)

(21) Appl. No.: 11/969,280

(22) Filed: Jan. 4, 2008

(51) Int. Cl. H01L 21/322

(52) U.S. Cl. 438/473; 257/E21.317

(57) ABSTRACT

A method embodiment deposits a dielectric layer over a transistor and then implants a gettering agent into the dielectric layer. The insulating layer into which the gettering agent is implanted comprises a single continuous insulating layer and is the insulating layer that borders the next layer of metallization. After this dielectric layer is formed, standard contacts (tungsten) are formed through the insulating layer to the source, drain, gate, etc. of the transistor. Additionally, reactive ion etching of the contacts is performed. The reactive ion etching process can create mobile ions; however, the gettering agent traps the mobile ions and prevents the mobile ions from contaminating the transistor.

### CROSS-REFERENCE TO RELATED APPLICATIONS

This application is related to U.S. application Ser. No. ______, having Attorney Docket Number FIS920070396US1, entitled “INTEGRATION OF ION GETTERING MATERIAL IN DIELECTRIC” filed concurrently herewith, the complete disclosure of which, in its entirety, is herein incorporated by reference.

### BACKGROUND

### Field of the Invention

The embodiments of the invention generally relate to integrated circuit devices and more particularly to a method that implants a gettering agent into insulating layers of transistors, where the gettering agent traps mobile ions and prevents the mobile ions from contaminating the underlying transistor.

### SUMMARY

More specifically, one method embodiment herein deposits a dielectric layer over a transistor and then implants a gettering agent into the dielectric layer. The gettering agent can comprise Phosphorus, Arsenic, Nitrogen, Xenon, etc. The insulating layer into which the gettering agent is implanted comprises a single continuous insulating layer and is the insulating layer that borders the next layer of metallization. After this dielectric layer is formed, standard contacts (tungsten) are formed through the insulating layer to the source, drain, gate, etc. of the transistor. Additionally, reactive ion etching of the contacts is performed. The reactive ion etching process can create mobile ions; however, the gettering agent traps the mobile ions and prevents the mobile ions from contaminating the transistor.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic diagram of a transistor structure according to embodiments herein;

FIG. 2 is a schematic diagram of a transistor structure according to embodiments herein;

FIG. 3 is a schematic diagram of a transistor structure according to embodiments herein; and

FIG. 4 is a schematic diagram of a transistor structure according to embodiments herein.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

Mobile ion contamination is a constant threat to semiconductor device performance and reliability. Mobile ions (i.e., K and Na) can shift the threshold voltage of field effect transistors (FETs) substantially, which causes reliability issues. Many mobile ions are produced by reactive ion etching (RIE) and/or chemical mechanical polishing CMP processes that are performed during and after the conductive contacts (Tungsten, Copper, etc.) to the various elements of the transistors/diodes (source, drain, gate, base, emitter, collector, etc.) are formed.

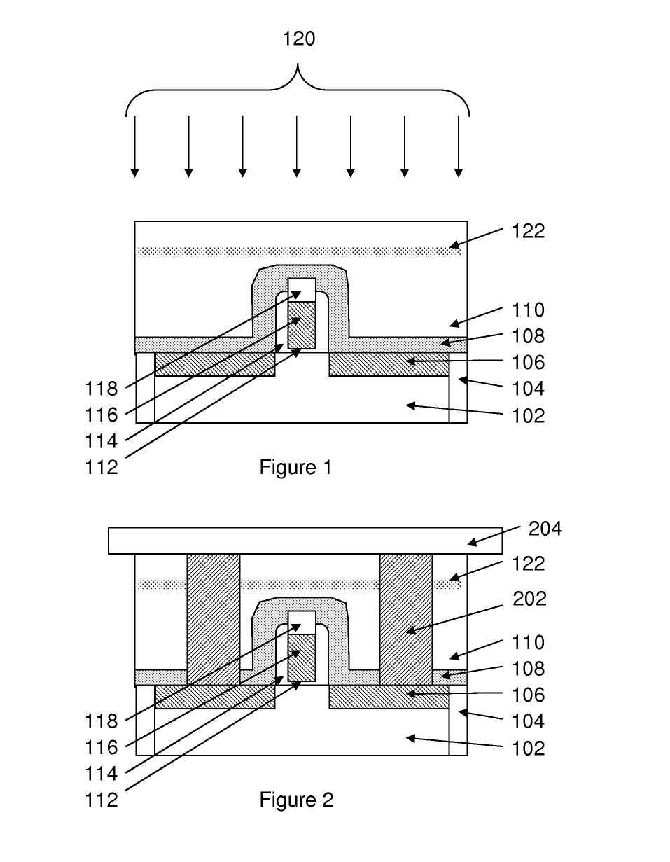

FIG. 1 illustrates a typical field effect transistor upon which embodiments herein operate. Such a field effect transistor includes a substrate 102 having a channel region; shallow trench isolation regions 104; source/drain regions 106; a gate oxide 112; a gate conductor 116 above the gate oxide 112; silicide 118 at the top of the gate conductor 116 and in source/drain regions 106; sidewall spacers 114 along the sides of the gate conductor 116; and an etch stop layer (nitride) 108. The various deposition, patterning, polishing, etching, etc. processes that are performed and the material selections that are made in the creation of such field effect transistors are well known as evidenced by U.S. Pat. No. 6,995,065 (which is incorporated herein by reference) and the details of such processing are not discussed herein to focus the reader on the salient aspects of the invention. Further, while one type of specific device is illustrated in the drawings, those ordinarily skilled in the art would understand that the invention is not strictly limited to the specific device shown, but instead that the invention is generally applicable to all similar devices that suffer disadvantageously from mobile ions.

One solution to the foregoing problems presented in this disclosure is an embodiment that deposits a conformal dielectric layer 110 (oxide, un-doped silicate glass (USG), etc.) over the nitride etch stop layer 108 of the transistor and then performs an implant 120 of a gettering agent into the dielectric layer to form a gettering region 122 within the dielectric 110, as shown in FIG. 1. The gettering agent can comprise Phosphorus, Arsenic, Nitrogen, Xenon, etc.

The insulating layer 110 into which said phosphorus is implanted comprises a single continuous insulating layer and is the insulating layer that borders the next layer of metallization 204 (shown in FIG. 2). After this dielectric layer 110 is formed and implanted, standard contacts 202 (Tungsten, Copper, etc.) are formed through the insulating layer to the source, drain, etc. of the transistor. Additionally, reactive ion etching and CMP of the contacts 202 is performed as part of the finalization/cleaning of the contacts.

As mentioned above, this reactive ion etching and CMP processes can create mobile ions; however, the gettering agent 112 traps the mobile ions and prevents the mobile ions from contaminating the transistor. By utilizing an implant 122 in the previously formed conformal dielectric layer, the structure will not experience problems relating to gap-fill, conformality, and mechanical stability.

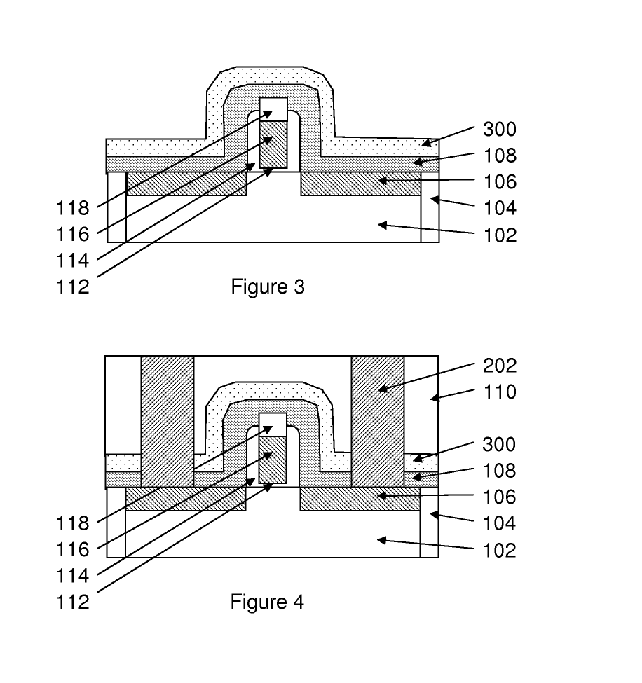

In a second embodiment, shown in FIGS. 3 and 4, prior to the formation of the conformal dielectric layer 110, a phosphorus silicate glass (PSG) layer 300 is deposited over the nitride layer 108. After this, the conformal dielectric 110 is deposited and the contacts 202 are formed, as described above. The PSG layer 300 forms an ion getter. While the PSG layer 300 is less conformal than the dielectric layer 110, the overall structure does not suffer from problems relating to gap-fill, conformality, and mechanical stability because the conformal nature of the overlying bioelectric 110 compensates for the lack of conformal to the in the PSG layer 300.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

1. A method comprising:
forming an insulating layer over a transistor;
implanting a gettering agent into said insulating layer, wherein said insulating layer into which said gettering agent is implanted comprises a single continuous insulating layer and comprises an insulating layer that borders a next layer of metallization; and
forming contracts through said insulating layer to said transistor.

2. The method according to claim 1, wherein said gettering agent comprises one of Phosphorus, Arsenic, Nitrogen, and Xenon.

3. (canceled)

4. A method comprising:
forming a phosphorous silicate glass (PSG) layer over a transistor;
forming an insulating layer over said PSG layer;
forming contracts through said insulating layer and said PSG layer to said transistor; and
performing at least one of reactive ion etching and chemical-mechanical polishing (CMP) of said contacts, wherein said reactive ion etching and said CMP creates mobile ions, and wherein said PSG layer traps said mobile ions and prevents said mobile ions from contaminating said transistor, wherein said PSG layer comprises a gettering agent.

5. (canceled)

6. The method according to claim 4, wherein said insulating layer comprises an insulating layer that borders a next layer of metallization.
